(19) United States
(12) Patent Application Publication
(10) Pub. No.: US 2021/0403321 A1
(43) Pub. Date: Dec. 30, 2021

(54) FORMATION OF SELF-ASSEMBLED MONOLAYER FOR ULTRASONIC TRANSDUCERS

(71) Applicants: Jianwei Liu, Fremont, CA (US); Keith G. Fife, Palo Alto, CA (US)

(72) Inventors: Jianwei Liu, Fremont, CA (US); Keith G. Fife, Palo Alto, CA (US)

(73) Assignee: Butterfly Network, Inc., Guilford, CT (US)

(21) Appl. No.: 17/362,834

(22) Filed: Jun. 29, 2021

Related U.S. Application Data
(60) Provisional application No. 63/046,586, filed on Jun. 30, 2020.

(51) Int. Cl. B81C 1/00; B06B 1/02; B81B 7/00; B81B 3/00

(52) U.S. Cl. CPC B81C 1/00968; B06B 1/0292; B81B 7/0003; B81B 3/0008; B81B 2203/04; B81B 2201/0271; B81B 2203/0127; B81B 2203/0315; B81C 1/00007

(57) ABSTRACT

Micromachined ultrasonic transducers having a self-assembled monolayer formed on a surface of a sealed cavity are described. A micromachined ultrasonic transducer may include a flexible membrane configured to vibrate over a sealed cavity, and the self-assembled monolayer may coat some or all of the interior surfaces of the sealed cavity. During fabrication, the sealed cavity may be formed by bonding the membrane to a substrate such that the sealed cavity is between the membrane and the substrate. An access hole may be formed through the membrane to the sealed cavity and the self-assembled monolayer is formed on surface(s) of the sealed cavity by introducing precursors into the sealed cavity through the access hole.

### CROSS-REFERENCE TO RELATED APPLICATIONS

The present application claims the benefit under 35 U.S.C. § 119(e) of U.S. Patent Application Ser. No. 63/046,586, filed Jun. 30, 2020 under Attorney Docket No. B1348.70184US00, and entitled “FORMATION OF SELF-ASSEMBLED MONOLAYER FOR ULTRASONIC TRANSDUCERS,” which is hereby incorporated by reference herein in its entirety.

### BACKGROUND

### Field

The present application relates to micromachined ultrasonic transducers.

### Related Art

Some micromachined ultrasonic transducers include a flexible membrane suspended above a substrate. A cavity is located between part of the substrate and the membrane, such that the combination of the substrate, cavity, and membrane form a variable capacitor. If actuated, the membrane may generate an ultrasound signal. In response to receiving an ultrasound signal, the membrane may vibrate, resulting in an output electrical signal.

### BRIEF SUMMARY

A method of forming an ultrasonic transducer having a self-assembled monolayer formed on a surface of a sealed cavity is described. The method comprises forming a sealed cavity by bonding a membrane to a substrate such that the sealed cavity is between the membrane and the substrate. One or more access holes through the membrane to the sealed cavity is formed and used in forming the self-assembled monolayer on the surface of the sealed cavity at least in part by introducing precursors into the sealed cavity through the one or more access holes.

### BRIEF DESCRIPTION OF DRAWINGS

Various aspects and embodiments of the application will be described with reference to the following figures. It should be appreciated that the figures are not necessarily drawn to scale. Items appearing in multiple figures are indicated by the same reference number in all the figures in which they appear.

FIG. 1 is a cross-sectional view of a micromachined ultrasound transducer, in accordance with some embodiments.

FIG. 2 is a schematic top view of an array of ultrasonic transducers and access holes in which the access holes are shared among the ultrasonic transducers.

FIG. 3 is a perspective view of an array of micromachined ultrasonic transducers comprising access holes for access to cavities of the micromachined ultrasonic transducer.

FIG. 4 is a schematic top view of the cavity layer of the structure of FIG. 3.

FIG. 5 illustrates a layer of the device of FIG. 3 including cavities and channels.

FIG. 6 is a flowchart of a fabrication process for forming an ultrasonic transducer having a SAM formed on a surface of a sealed cavity, according to some embodiments.

FIG. 7 is flowchart of a fabrication process for forming a SAM on a surface of a sealed cavity of an ultrasonic transducer, according to some embodiments.

FIG. 8 is a schematic of the SAM formation process 600 and process 700 shown in FIG. 6 and FIG. 7, respectively.

### DETAILED DESCRIPTION

Aspects of the present application provide a micromachined ultrasonic transducer (MUT) comprising a self-assembled monolayer (SAM) formed on a surface of a sealed cavity. SAMs are molecular assemblies formed spontaneously on surfaces by adsorption and organized into large ordered domains. The SAM is a close-packed monolayer having low surface energy that could act as an anti-stiction surface and, in some instances, an anti-charging layer for a tribological interface in microelectromechanical systems (MEMs).

One type of MUT is a capacitive micromachined ultrasound transducer (CMUT) having a structure of a parallel plate capacitor with a rigid bottom electrode and a top electrode residing on or within a flexible membrane where a sealed cavity is defined between the bottom and top electrodes. The present application describes techniques for forming a SAM on a surface of the sealed cavity. In some embodiments, the SAM may form a coating for the interior surface of the sealed cavity. The SAM may act to lower surface energy on the CMUT contact interface, which may increase membrane movement speed and reduce energy loss during operation. The SAM may also reduce stiction between the top and bottom electrodes and charge accumulation in the membrane. For example, as the membrane moves during operation it may come in physical contact with the bottom of the cavity and the SAM may reduce charging on the membrane caused by repeated contacts with the bottom of the cavity. These benefits of having a SAM may enhance acoustic pressure and improve lifetime of the CMUT sensor.

In addition, the SAM may provide certain benefits for CMUT sensors configured to operate in multiple modes, including multiple modes having different frequency ranges. In some embodiments, a CMUT sensor may operate in “collapsed mode” and in “non-collapsed mode.” As described herein, a “collapsed mode” refers to a mode of operation in which at least a portion of a CMUT membrane is mechanically fixed (e.g., to a surface of the cavity) and at least a portion of the membrane is free to vibrate based on a changing voltage differential between the electrode and the membrane. In “non-collapsed mode,” the membrane is not mechanically fixed and is free to vibrate. A benefit of operating in collapsed mode is that a CMUT sensor is capable of generating more power at higher frequencies. Switching operation of multiple ultrasonic transducers from non-collapsed mode to collapsed mode (and vice versa) allows the ultrasound probe to change the frequency range at which the highest power ultrasound signals are being emitted. For example, a CMUT sensor may operate in a first mode associated with a first frequency range (e.g., 1-5 MHz, with a peak power frequency of 3 MHz) by operating in a non-collapsed mode and in a second mode associated with a second frequency range (e.g., 5-9 MHz, with a peak power frequency of 7 MHz) by operating in a collapsed mode. Forming a SAM on the sealed cavity of a CMUT configured to operate in both collapsed mode and non-collapsed mode may prevent or reduce stiction of the membrane to a surface, particularly when switching from collapsed mode to non-collapsed mode.

A MUT (e.g., CMUT) may comprise one or more access holes, which may function to control the pressure within a sealed cavity during manufacture of the MUT. The access hole may represent a pressure port for the sealed cavity. Some ultrasound devices comprise large numbers of MUTs, such as hundreds, thousands, or hundreds of thousands of MUTs. Operation of such ultrasound devices may benefit in terms of accuracy and dynamic range (e.g., by minimizing damping) from having a substantially equal or uniform pressure across the area of the MUTs. Thus, providing pressure ports for individual MUTs or sub-groups of MUTs of the ultrasound device may facilitate achieving more uniform pressure across the sensing area. Once the pressure of the cavity, or cavities, is set as desired, the access hole may be sealed. Such access holes may be particularly useful when low temperature bonding techniques are used to form the cavity, or cavities, because some outgassing may occur during bonding. In contrast, high temperature bonding techniques may involve performing the bonding of two substrates in a vacuum and do not necessarily require the use of access holes for outgassing. Accordingly, the techniques described herein for forming a SAM on a cavity may be implemented where the cavity is formed using low temperature bonding techniques that involve the use of access holes for outgassing. In this way, the access holes may both allow for outgassing during bonding and introducing precursor molecules during formation of the SAM in the cavity.

Aspects of the present application relate to forming a self-assembled monolayer (SAM) on a surface of a sealed cavity of a MUT by using the access holes during manufacture of the ultrasonic transducer. In a CMUT, a sealed cavity is formed by bonding a membrane to a substrate such that the sealed cavity is between the membrane and the substrate. An access hole formed through material (e.g., the membrane, an electrode, oxide material connecting the membrane to the substrate) to the sealed cavity may be used in forming the SAM, and may also act as a pressure port used to set the pressure of the cavity in the resulting CMUT sensor. In particular, forming the SAM may involve introducing precursors into the sealed cavity through one or more access holes.

In some embodiments, an activation process may be performed as part of forming the SAM to activate the surface of the sealed cavity prior to introduction of the precursors. The activation process may involve introducing one or more materials (e.g., ozone, oxygen plasma, water vapor) into the sealed cavity through the access hole. In some embodiments, a layer of dielectric material may be formed within the sealed cavity prior to forming the self-assembled monolayer. In such embodiments, the self-assembled monolayer may be formed on the layer of dielectric.

Some embodiments may involve forming the SAM through multiple cycles of introducing precursor molecules through one or more access holes followed by an incubation time. The incubation time may be on the order of minutes to hours. Performing multiple cycles where precursor molecules are introduced into the cavity followed by an incubation time may allow for a high-quality SAM layer having closely-packed and aligned precursor molecules to form on one or more surfaces of the cavity. During each cycle, additional precursor molecules may be absorbed on the surface of the cavity and the molecules may rearrange into closely-packed, aligned domains.

A benefit of the techniques described herein for using one or more access holes when forming the SAM is that the SAM is formed after the cavity is formed. The cavity may be formed by bonding two substrates (e.g., wafers) together. If the SAM was formed on the substrates separately prior to bonding, the SAM may prevent or reduce the ability of the two substrates to bond together because the SAM lowers the surface energy of the substrates. In contrast, the techniques described herein relate to forming the SAM after any bonding process used to form the cavity, allowing for the bonding process to not be impacted by the SAM.

According to the techniques described herein, the SAM may coat the entire surface of the sealed cavity of the CMUT, including one or more materials that form surface(s) of the sealed cavity. In some embodiments, the sealed cavity may include getter material positioned in the sealed cavity. The getter material may be used to absorb gases during the bonding process. Using the one or more access holes may result in forming the SAM over the getter material. In some embodiments, the sealed cavity may include oxide material formed over an electrode of the CMUT and the SAM may be formed over the oxide material using the techniques described herein. For some embodiments, the SAM may be formed on a surface of the membrane that forms the sealed cavity.

The aspects and embodiments described above, as well as additional aspects and embodiments, are described further below. These aspects and/or embodiments may be used individually, all together, or in any combination of two or more, as the application is not limited in this respect.

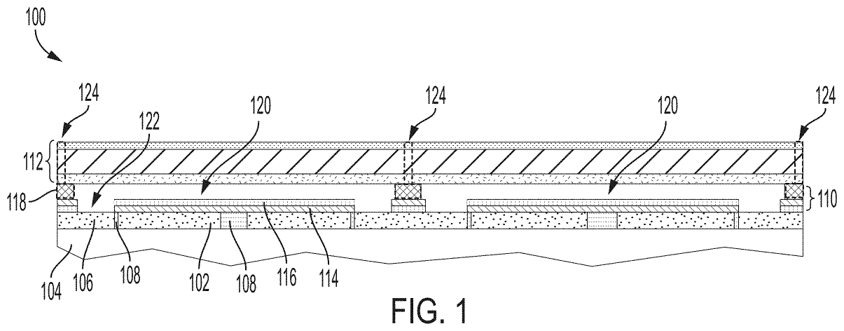

FIG. 1 is a cross-sectional view of a micromachined ultrasound transducer 100 in accordance with some embodiments. Ultrasound transducer 100 includes a lower electrode 102 formed over a substrate 104 (e.g., a CMOS substrate, such as silicon). The CMOS substrate 104 may include, but is not necessarily limited to, CMOS circuits, wiring layers, redistribution layers, and insulation/passivation layers. Examples of suitable materials for the lower electrode 102 include one or more of titanium (Ti), zirconium (Zr), vanadium (V), cobalt (Co), nickel (Ni), as well as alloys thereof. In some instances, the micromachined ultrasound transducer 100 may be directly integrated on an integrated circuit that controls the operation of the transducer. In the context of a CMUT, one way of manufacturing a CMUT ultrasound device is to bond a membrane substrate to an integrated circuit substrate, such as a complementary metal oxide semiconductor (CMOS) substrate.

As shown in FIG. 1, the lower electrode 102 is electrically isolated from adjacent metal regions 106 that are also formed on the substrate 104. Exposed portions of the adjacent metal regions 106 may thus serve as a getter material during cavity formation. The adjacent metal regions 106 may be formed from a same metal material as the lower electrode 102, and are electrically isolated from the lower electrode 102 by an insulator material 108 (e.g., silicon oxide). It should be appreciated that although the geometric structure of this portion of the ultrasound transducer 100 is shown to be generally circular in shape as described herein, other configurations are also contemplated such as for example, rectangular, hexagonal, octagonal, and other multi-sides shapes, etc. Additional examples of gettering techniques that may be used in an ultrasonic transducer as described in the present application may be found in U.S. patent application Ser. No. 16/585,283, published on Apr. 2, 2020 as Publication No.: U.S. 2020/0102214, which is incorporated by reference herein in its entirety.

An insulator layer (e.g., one or more individual insulator layers, such as an insulator stack 110) is formed over the lower electrode 102 and portions of adjacent metal regions 106. Portions of insulator stack 110 provide support for a moveable membrane 112 (e.g., an SOI wafer having a doped silicon device layer with an oxidized surface) bonded to the stack 110. In the illustrated embodiment, the insulator stack 110 includes a first oxide layer 114 (e.g., chemical vapor deposition (CVD) silicon oxide), a second oxide layer 116 (e.g., atomic layer deposition (ALD) aluminum oxide) and a third oxide layer 118 (e.g., sputter deposited silicon oxide). By suitable lithographic patterning and etching of the third oxide layer 118, a cavity 120 may be defined for the ultrasound transducer 100. Further, in embodiments where the second oxide layer 116 is chosen from a material having an etch selectivity with respect to the third oxide layer 118, the second oxide layer 116 may serve as an etch stop for removing portions of the third oxide layer 118 in order to define the cavity 120.

In addition to the etch of the third oxide layer that defines the cavity 120, another etch is used to define openings 122 through the second oxide layer 116 and first oxide layer 114, thereby exposing a top surface of a portion of metal regions 106. The exposed portions of metal regions 106 may advantageously serve as a getter material of one or more gases present during a bonding operation of the membrane 112 to seal the cavity 120.

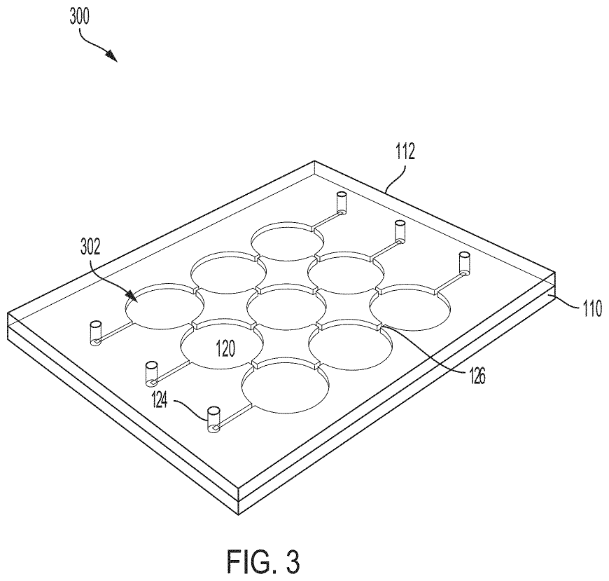

Micromachined ultrasound transducer 100 includes access holes 124 shared among the ultrasonic transducers, including those shown in FIG. 1. The access holes 124 may have any suitable location. In the illustrated non-limiting example, they are positioned between two cavities 120. In such embodiments, an access hole may be formed in a region separate from the cavity where the membrane moves during operation. As shown in FIG. 1, an access hole may be formed in a region over insulator stack 110. However, alternative configurations are possible. For example, an access hole may be provided for each individual cavity. As yet another example, access holes may be disposed at the periphery of the array, such as shown in FIG. 3. Alternatively, fewer access holes may be provided than shown, with additional channels provided to allow for control of the cavity pressure across the array. In some embodiments, one or more access holes 124 may be shared by two or more CMUTs. For some embodiments, the number of access holes 124 in an array of CMUTS may be less than or equal to half the number of CMUTs. For example, if there are 9,000 CMUTs in an array, then there may be approximately 4,500 access holes. In some embodiments, an access hole may pass through a membrane of a CMUT over the cavity. For example, an access hole may be formed at a region of the membrane that does not impact the stress of the membrane (e.g., center of the membrane over an underlying cavity).

According to the techniques described herein, access holes 124 may be used to form a self-assembled monolayer (SAM) (not shown in FIG. 1) on one or more surfaces of cavity 120. In some embodiments, a SAM may be formed over second oxide layer 116, over exposed portions of metal regions 106, on a side of membrane 112 proximate to cavity 120, and/or on a side of insulator stack 110. The SAM may lower the surface energy of surface(s) of cavity 120 and act as an anti-wetting surface. For example, without the SAM, a surface of the cavity may have a water contact angle of less than 15 degrees, but with the SAM formed on the surface may result in the surface having a water contact angle of approximately 90 degrees.

The access holes may have any suitable dimensions and may be formed in any suitable manner. In some embodiments, the access holes are sufficiently small to not have a negative impact on the performance of the ultrasonic transducers. Also, the access holes may be sufficiently small to allow them to be sealed once the pressures of cavities 120 are set to a desired value. For example, the access holes may have diameters between approximately 0.1 microns and approximately 20 microns, including any value or range of values within that range. In some embodiments, the access holes may have diameters between 0.1 microns and 1 micron, between 0.3 microns and 0.8 microns, or between 0.5 microns and 0.6 microns. The access holes may be sealed in any suitable manner, such as with one or more metal materials. For example, aluminum may be sputtered to seal the access holes. The metal material that seals the access holes may have thicknesses between 2 microns and 5 microns, including any value or range of values within that range.

The access holes may be created and used during manufacture of the MUT(s). In some embodiments, the sealed cavities may be formed using wafer bonding techniques. The wafer bonding techniques may be inadequate for achieving uniform cavity pressure across a wafer or array of MUTs. Also, the chemicals present for wafer bonding may unequally occupy or remain in certain cavities of an array of MUTs. After the cavities are sealed (for example, by the wafer bonding), the access holes may be opened. The pressures of the sealed cavities may then be equalized, or made substantially equal, through exposure of the wafer to a desired, controlled pressure. Also, desired chemicals (e.g., Argon) may be introduced to the cavities through the access holes. Subsequently, the access holes may be sealed.

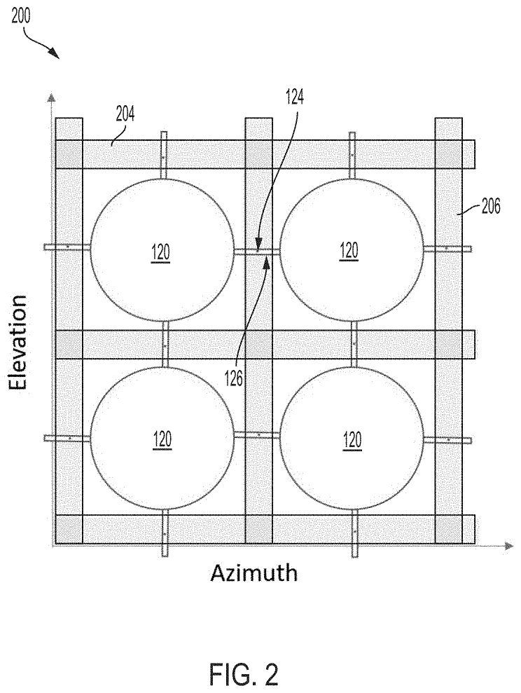

FIG. 2 illustrates an array of ultrasonic transducers and pressure ports in which the pressure ports are shared among the ultrasonic transducers, such as shown in FIG. 1. The ultrasound device 200 includes cavities 120, metal lines 204 and 206, channels 126 and access holes 124. The pressure ports may represent a combination of channels 126 and access holes 124. The access holes may extend vertically, for example perpendicular to the cavities 120, as shown in FIG. 2 as openings 124. The channels 126 may interconnect neighboring cavities 120 as shown. In this example, the pressure ports are accessible internal to the array as opposed to being disposed at a periphery of the array. As shown in FIG. 2, metal lines 204 and 206 are formed over access holes 124 to seal access holes 124. Metal lines 204 and 206 may have thicknesses between 2 microns and 5 microns, including any value or range of values within that range.

Although only four cavities are shown in ultrasound device 200 of FIG. 2, it should be appreciated that any suitable number of ultrasound transducers may be formed in an array of an ultrasound device. An ultrasound device may have between 1,000 and 20,000 ultrasound transducers, including any value or range of values within that range. In some embodiments, an ultrasound device may have between 1,000 and 10,000, between 5,000 and 10,000, between 6,000 and 12,000, between 8,000 and 15,000, or between 15,000 and 20,000 ultrasound transducers. In some embodiments, the number of access holes in an ultrasound transducer array may be less than or equal to half the number of ultrasound transducers. For example, if there are 9,000 CMUTs, then there may be less than or equal to 4,500 access holes formed in the array.

FIG. 3 is a non-limiting example, and is a perspective view of an array of micromachined ultrasonic transducers comprising pressure ports for access to cavities of the micromachined ultrasonic transducer. The ultrasound device 300 comprises an array of nine MUTs 302, formed by a membrane 112, insulating layer 110, and cavities 120. Access holes 124 are provided, and channels 126 interconnect the cavities 120. As shown in FIG. 3, access holes 124 are disposed at the periphery of the array where control over the cavity pressure of the cavities internal to the array may still be achieved because of the presence of channels 126, which may be air channels. In some embodiments, insulating layer 110 may be a part of a complementary metal-oxide-semiconductor (CMOS) wafer, and cavities 120 can be formed in insulating layer 110 of the CMOS wafer.

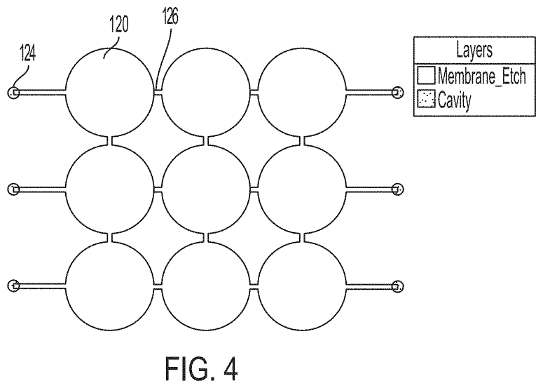

FIG. 4 illustrates a top view of the cavity layer of the ultrasound device 300 of FIG. 3. As shown, nine cavities are included, interconnected by channels 126. Again, the channels 126 may be air channels, allowing pressure in the adjoining cavities to be set at a uniform level. The channels 126 may have any suitable dimensions for this purpose, such as being between 0.1 microns and 20 microns, including any value or range of values within that range.

The ultrasound device of FIGS. 3 and 4 is a non-limiting example. The number of micromachined ultrasonic transducers shown, the shape, dimensions, and positioning are all variables. For example, FIG. 4 illustrates circular cavities, but other shapes are possible, such as polygonal, square, or any other suitable shape. The positioning and number of pressure ports shown may also be selected for a particular application.

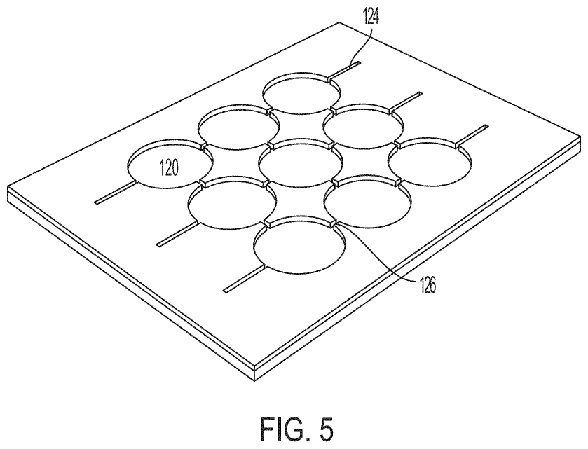

FIG. 5 illustrates a perspective view of the cavity layer of the device of FIG. 3 including cavities and channels. In this figure, the membrane layer of the ultrasound device 300 is omitted. The cavities 120, channels 126, and part of the access holes 124 may be formed, for example by etching. Subsequently, the membrane 112 may be formed to seal the cavities 120 by creating a membrane layer. A vertical part of the access holes 124 may then be etched through the membrane 112 to form the ultrasound device 300. Additional examples of ultrasonic transducers having pressure ports that may be used in accordance with the techniques described herein may be found in U.S. patent application Ser. No. 16/401,870, published on Nov. 7, 2019 with Publication No.: U.S. 2019/0336099, which is incorporated by reference herein in its entirety.

As described herein, access holes may be used in the formation of a self-assembled monolayer (SAM) on a surface of the sealed cavity of an ultrasonic transducer. In particular, the sealed cavity is formed by bonding a membrane to a substrate such that the sealed cavity is between the membrane and the substrate and one or more access holes may be formed through the membrane to the sealed cavity. Prior to sealing the access hole, a SAM is formed on a surface of the sealed cavity by introducing precursors into the sealed cavity through the one or more access holes. After formation of the SAM, the one or more access holes may be sealed as part of setting the pressure for the sealed cavity. In some embodiments, the SAM may form on substantially the entire surface of the sealed cavity. In such instances, the SAM may be considered to coat the sealed cavity. In other embodiments, the SAM may only form on certain regions or materials that form sides of the sealed cavity. For example, in some embodiments, a SAM may form on dielectric material forming one or more sides of the cavity. In some embodiments, a SAM may form on getter material of the cavity. In some embodiments, a SAM may form on a side of the membrane that forms the cavity.

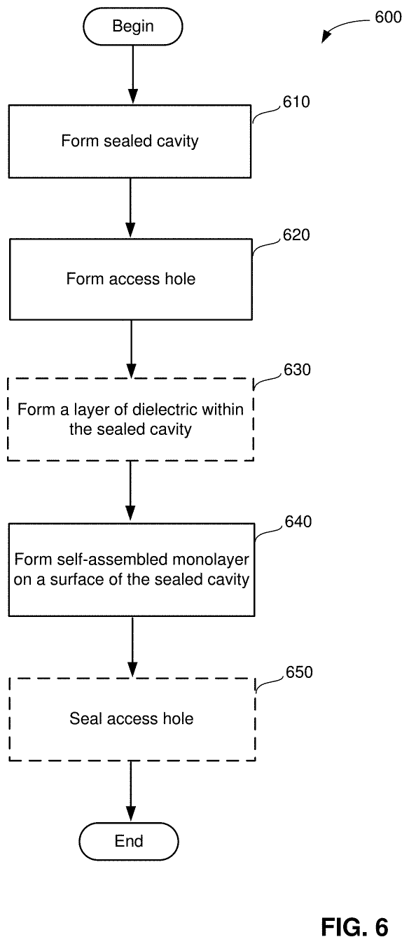

FIG. 6 is a flowchart of fabrication process 600 to form a MUT having a SAM on a surface of a sealed cavity of the MUT, such as MUT 100 shown in FIG. 1, MUTs in ultrasound device 200 shown in FIG. 2, and MUTs in ultrasound device 300 shown in FIGS. 3, 4, and 5. First, in act 610, a sealed cavity, such as cavities 120, is formed. The sealed cavity may be formed by bonding a membrane to a substrate such that the sealed cavity is between the membrane and the substrate. The membrane and the substrate may be bonded using a wafer bonding process, which may be a low temperature wafer bonding process, according to some embodiments. The wafer bonding process may also include a post-process annealing step.

Next, in act 620, one or more access holes are formed through the membrane to the sealed cavity. An access hole may be formed using any suitable etch process, including reactive ion etching (RIE) and deep reactive ion etching (DRIE).

In some embodiments, process 600 may then proceed to act 630, where a layer of dielectric is formed within the sealed cavity. The layer of dielectric may include Al₂O₃. The layer of dielectric may be formed using any suitable process through the one or more access holes. In some embodiments, the layer of dielectric may be formed using an atomic layer deposition (ALD) process. In some embodiments, the layer of dielectric may form some or all of second oxide layer 116 shown in FIG. 1.

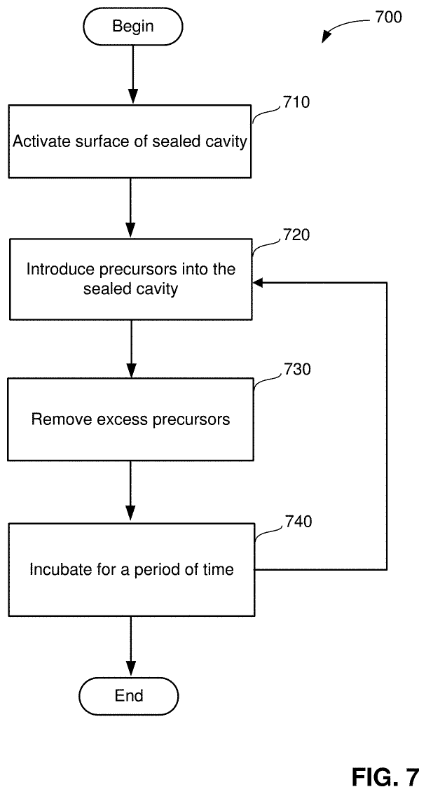

Next, in act 640, a self-assembled monolayer (SAM) is formed on a surface of the sealed cavity. The SAM is formed at least in part by introducing precursors into the sealed cavity through the one or more access holes. Examples of precursors that may be used to form the SAM include hydrocarbon silane, such as octadecyltrichlorosilane (OTS), and perfluorocarbon silane, such as 1H, 1H, 2H, 2H-perfluorodecyltrichlorosilane (FDTS). Additional steps that may be involved in forming the SAM are described in fabrication process 700 shown in FIG. 7. In embodiments where process 600 includes act 630, the SAM may be formed on the layer of dielectric.

In some embodiments, act 640 may involve forming the SAM through multiple cycles of introducing precursor molecules through one or more access holes followed by an incubation time. During each cycle, additional precursor molecules may be absorbed on the surface of the cavity and the molecules may rearrange into closely packed, aligned domains. The incubation time may be on the order of minutes to hours. In some embodiments, the number of cycles may be between 2 and 10, between 4 and 8, or between 5 and 7.

Forming the SAM lowers the surface energy of one or more surfaces of the cavity. One measure of surface energy is water contact angle. Thus, a surface of the sealed cavity after forming the SAM has a higher water contact angle than a surface of the sealed cavity prior to forming the SAM. In some embodiments, the surface of the sealed cavity after forming the SAM may have a water contact angle in the range between 75 degrees and 100 degrees, including any value or range of values in that range. For example, a surface of the cavity prior to forming the SAM may have a water contact angle less than or equal to 15 degrees and the surface of the cavity after forming the SAM may have a water contact angle approximately equal to 90 degrees.

In some embodiments, process 600 may then proceed to act 650, where the one or more access holes sealed. An access hole may be sealed so that the cavity, or cavities, remain at a suitable pressure for operation of the ultrasonic transducer. In some embodiments, sealing the one or more access holes may involve forming one or more metals at an end of an access hole (e.g., the end of the access hole at the exposed surface of the membrane). The one or more metals that seal the access holes may have thicknesses between 2 microns and 5 microns, including any value or range of values within that range. The access hole may be sealed by any suitable material, or by any suitable process, such as but not limited to a sputtering process. The access hole may be sealed by a multilayered structure formed of multiple materials. Example materials include Al, Cu, Al/Cu alloys, and TiN in any suitable combination.

In some embodiments, prior to sealing the access hole, one or more materials may be removed from a top surface of the membrane. In some embodiments, a SAM coating on the top surface of the membrane is removed. For example, during the SAM formation process a SAM may form on an exterior surface of the membrane, such as the top surface of membrane 112 shown in FIG. 1, and may be removed prior to setting a pressure for the sealed cavity and sealing the access hole. In some embodiments, dielectric material, such as dielectric material formed during act 630, on the top surface of the membrane is removed. The one or more materials may be removed from the top surface of the membrane using a sputter etch process.

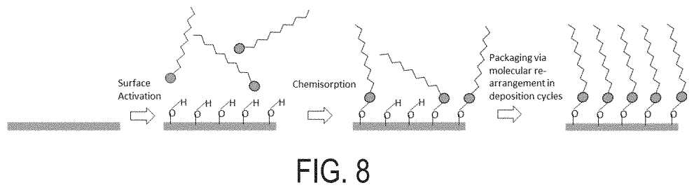

FIG. 7 is a flowchart of fabrication process 700 to form a SAM on a surface of a sealed cavity of a MUT, such as act 640 shown in FIG. 6. FIG. 8 is a schematic of the SAM formation process 700. SAMs are formed by the chemisorption of precursors, which consist of a “head group” and “tail groups”, onto a substrate from either a vapor or liquid phase. First, in act 710, a surface of a sealed cavity is activated. Activation of the surface may allow for the generation of sufficient adsorption sites for the precursors, which may further allow for the formation of a densely packed monolayer. Activating the surface of the sealed cavity may involve introducing one or more materials into the sealed cavity through one or more access holes. In some embodiments, a first material may be introduced into the sealed cavity followed by a second material. Examples of the first material include ozone or oxygen plasma. An example of the second material is water vapor.

Next, in act 720, precursors are introduced into the sealed cavity through the one or more access holes. Examples of precursors that may be used to form the SAM include hydrocarbon silane, such as octadecyltrichlorosilane (OTS), and perfluorocarbon silane, such as 1H, 1H, 2H, 2H-perfluorodecyltrichlorosilane (FDTS).

Next, in act 730, excess precursors are removed through the one or more access holes. The excess precursors may be pumped out through the one or more access holes, leaving predominately precursors that are adsorbed on the surface. At this stage the surface may be covered by adsorbed molecules in a disordered form.

Next, in act 740, the structure is allowed to incubate for a period of time. The period of time may be on the order of minutes to hours to allow for a slow organization of the adsorbed molecules to gradually convert from a disordered structure into a crystalline or semicrystalline structure on the surface. In particular, the “head groups” of the precursors assemble together on the substrate, while the “tail groups” of the precursors assemble far from the substrate. Areas of close-packed molecules nucleate and grow, while substrate surface without coverage is exposed.

Acts 720, 730, and 740 may be repeated until a desired SAM is formed. In some embodiments, the deposition of the precursors and incubation cycle is repeated multiple times until the surface of the cavity is substantially fully covered in a single monolayer. In some embodiments, the number of cycles of repeating acts 720, 730, and 740 may be between 2 and 10, between 4 and 8, or between 5 and 7.

Various types of ultrasound devices may implement MUTs with a SAM formed on a surface of a sealed cavity of the types described herein. In some embodiments, a handheld ultrasound probe may include an ultrasound-on-a-chip comprising MUTs with a SAM. In some embodiments, an ultrasound patch may implement the technology. A pill may also utilize the technology. Thus, aspects of the present application provide for such ultrasound devices to include MUTs with pressure ports.

Having thus described several aspects and embodiments of the technology of this application, it is to be appreciated that various alterations, modifications, and improvements will readily occur to those of ordinary skill in the art. Such alterations, modifications, and improvements are intended to be within the spirit and scope of the technology described in the application. It is, therefore, to be understood that the foregoing embodiments are presented by way of example only and that, within the scope of the appended claims and equivalents thereto, inventive embodiments may be practiced otherwise than as specifically described.

As described, some aspects may be embodied as one or more methods. The acts performed as part of the method(s) may be ordered in any suitable way. Accordingly, embodiments may be constructed in which acts are performed in an order different than illustrated, which may include performing some acts simultaneously, even though shown as sequential acts in illustrative embodiments.

All definitions, as defined and used herein, should be understood to control over dictionary definitions, definitions in documents incorporated by reference, and/or ordinary meanings of the defined terms.

The phrase “and/or,” as used herein in the specification and in the claims, should be understood to mean “either or both” of the elements so conjoined, i.e., elements that are conjunctively present in some cases and disjunctively present in other cases.

As used herein in the specification and in the claims, the phrase “at least one,” in reference to a list of one or more elements, should be understood to mean at least one element selected from any one or more of the elements in the list of elements, but not necessarily including at least one of each and every element specifically listed within the list of elements and not excluding any combinations of elements in the list of elements.

As used herein, the term “between” used in a numerical context is to be inclusive unless indicated otherwise. For example, “between A and B” includes A and B unless indicated otherwise.

The terms “approximately” and “about” may be used to mean within ±20% of a target value in some embodiments, within ±10% of a target value in some embodiments, within ±5% of a target value in some embodiments, and yet within ±2% of a target value in some embodiments. The terms “approximately” and “about” may include the target value.

1. A method of forming an ultrasonic transducer, the method comprising:
forming a sealed cavity by bonding a membrane to a substrate such that the sealed cavity is between the membrane and the substrate;
forming at least one access hole through the membrane to the sealed cavity; and
forming a self-assembled monolayer on at least one surface of the sealed cavity at least in part by introducing precursors into the sealed cavity through the at least one access hole.

2. The method of claim 1, wherein the method further comprises forming a layer of dielectric within the sealed cavity prior to forming the self-assembled monolayer, and wherein forming the self-assembled monolayer comprises forming the self-assembled monolayer on the layer of dielectric.

3. The method of claim 2, wherein the layer of dielectric includes Al₂O₃ and forming the layer of dielectric further comprises using an atomic layer deposition (ALD) process.

4. The method of claim 1, wherein forming the self-assembled monolayer further comprises activating the at least one surface of the sealed cavity by introducing one or more materials into the sealed cavity through the at least one access hole prior to introducing the precursors into the sealed cavity.

5. The method of claim 4, wherein activating the at least one surface of the sealed cavity further comprises introducing ozone or oxygen plasma into the sealed cavity through the at least one access hole followed by introducing water vapor into the sealed cavity through the at least one access hole.

6. The method of claim 1, wherein the method further comprises sealing the at least one access hole.

7. The method of claim 6, wherein sealing the at least one access hole further comprises forming metal material over the at least one access hole.

8. The method of claim 6, wherein the method further comprises removing at least one portion of self-assembled monolayer formed on a surface of the membrane prior to sealing the at least one access hole.

9. The method of claim 1, wherein the precursors are molecules selected from the group consisting of hydrocarbon silane and fluorocarbon silane.

10. The method of claim 1, wherein forming the self-assembled monolayer further comprises repeating the step of introducing precursors into the sealed cavity through the at least one access hole.

11. The method of claim 1, wherein forming the sealed cavity further comprises bonding the membrane to an insulator stack, and forming the at least one access hole further comprises forming one or more of the at least one access hole over the insulator stack.

12. The method of claim 11, wherein the substrate comprises a bottom electrode, and the insulator stack is formed over the bottom electrode.

13. The method of claim 11, wherein the insulator stack includes at least one oxide layer selected from the group consisting of chemical vapor deposition (CVD) silicon oxide, atomic layer deposition (ALD) aluminum oxide, and sputter deposited silicon oxide.

14. The method of claim 1, wherein a surface of the sealed cavity after forming the SAM has lower surface energy than a surface of the sealed cavity prior to forming the SAM.

15. The method of claim 1, wherein a surface of the sealed cavity after forming the SAM has a higher water contact angle than a surface of the sealed cavity prior to forming the SAM.

16. The method of claim 1, wherein the substrate comprises a bottom electrode, the membrane comprises a top electrode, and the sealed cavity is formed between the top electrode and the bottom electrode.
